(19) United States
(12) Patent Application Publication
(10) Pub. No.: US 2017/0108598 A1
(43) Pub. Date: Apr. 20, 2017

(54) BORON BASED THIN-FILM COATINGS

(71) Applicant: INTEGRATED SENSORS, LLC, Ottawa Hills, OH (US)

(72) Inventor: Peter S. FRIEDMAN, Ottawa Hills, OH (US)

(21) Appl. No.: 15/293,636

(22) Filed: Oct. 14, 2016

Related U.S. Application Data
(60) Provisional application No. 62/284,938, filed on Oct. 14, 2015.

(51) Int. Cl. G01T 3/08; H01C 7/00; H01L 49/02

(52) U.S. Cl. CPC G01T 3/08; H01L 28/20; H01C 7/006

(57) ABSTRACT

An apparatus includes a first layer of a rare earth element. The apparatus further includes a thin-film coating layer deposited on the first layer, where the thin-film coating layer includes boron.

### RELATED APPLICATIONS

This application claims priority to U.S. Provisional Patent Application Ser. No. 62/284,938 filed Oct. 14, 2015, the specification of which is herein incorporated by reference.

### FIELD

One embodiment is directed generally to thin-film coatings, and in particular to boron based thin-film coatings.

### BACKGROUND INFORMATION

A thin-film coating is a layer of material ranging from fractions of a nanometer to several micrometers in thickness. A thin-film coating is typically provided using a deposition process, which is a controlled synthesis of materials as thin-films. Advances in thin-film deposition techniques have been a significant step in the development and improvements of a wide range of technology, including magnetic recording media, electronic semiconductor devices, LEDs, optical coatings (such as antireflective coatings), hard coatings on cutting tools, energy generation (e.g., thin film solar cells and thin-film batteries) and drug delivery.

### SUMMARY

One embodiments is an apparatus that includes a first layer of a rare earth element. The apparatus further includes a thin-film coating layer deposited on the first layer, where the thin-film coating layer includes boron.

### BRIEF DESCRIPTION OF THE DRAWINGS

FIG. 1 is a perspective view of a surface-discharge plasma panel sensor with a parallel/rectilinear surface-discharge electrode pattern incorporating individual cell quenching resistors and an electrode pattern that can incorporate the thin-film overcoat layers in accordance with one embodiment.

FIG. 2 is a cross-sectional view of a microcavity-PPS neutron detector showing two adjacent microcavity pixels in accordance with one embodiment.

FIG. 3 is a top view of a honeycomb structure with each cavity being hexagon shaped with a staggered row arrangement in accordance with one embodiment.

### DETAILED DESCRIPTION

One embodiment uses thin-film overcoat layers of boron, either in the form of elemental boron (“B”), or boron carbide (“B₄C”), or boron nitride (“BN”), as a protective layer over rare earth metals, such as gadolinium (“Gd”), europium (“Eu”), lanthanum (“La”), neodymium (“Nd”), etc. The rare earth metals normally form unstable flaky oxides in moist air that spall off, leading to rapid corrosion and sometimes complete disintegration of the bulk rare earth metal. However, the thin-film overcoat layers in accordance to embodiments of the invention serve to prevent this disintegration.

In general, Gd, like many of the rare earth elements, rapidly forms a “flaky” surface oxide when exposed to moist air. This loosely adhering surface oxide quickly spalls off as a colorless (or white) powder within hours or days, thereby exposing more metal surface to rapid oxidation. This cycle of continuous oxide corrosion can rapidly lead to complete disintegration of the entire Gd metal layer within days, or months, or longer, depending on the layer thickness and the ambient humidity.

However, embodiments remedy this surface oxide flaking problem in ambient air, without significantly affecting the Gd atomic properties, by depositing a low density, non-porous, hard thin-film surface coating with strong adhesion to the underlying Gd layer. Although embodiments are applicable to all elements that exhibit this oxidation problem (e.g., iron (“Fe”)), it is particularly relevant to the rare earth metals, including the Lanthanide and Actinide series, and in particular Gd, Eu, La, and Nd. Further, in one embodiment that uses Gd as a neutron conversion layer, the disclosed thin-film surface coating can itself function as a supplemental neutron conversion layer. In addition to being extremely thin and low density (i.e., highly transparent to emitted Gd conversion electrons), the coating in accordance with embodiments has the benefit of using a low atomic number material that minimizes further backscattering (i.e., beyond that from the bulk Gd itself) and absorption of the emitted Gd conversion electrons.

In one embodiment, “thin-film” refers to an effective thickness generally less than ˜5 μm, and often a thickness of less than 0.5 μm. In other embodiments, the thickness can be less than 0.01 μm. For Gd as a neutron conversion layer, the boron protective overcoat can provide further benefits by using the boron-10 isotope (¹⁰B) which in itself is a neutron conversion material and yields a slightly lower density coating than the principal ¹¹B isotope. In this regard, ¹⁰B also has a slightly lower density than ¹⁰B₄C, so for a given mass-areal coating, there is less boron present in B₄C than in an equivalent mass-areal coating of pure (i.e., neat) boron. However, for this application the protective overcoat layer can utilize either a thin-film of elemental ¹⁰B or ¹⁰B₄C, because both materials are slightly conductive and the coating should not be an electrical insulator. In other embodiments, natural boron (i.e., 19.9% ¹⁰B, and 80.1% ¹¹B) in the form of elemental B or B₄C can be used.

Embodiments further involve the use of a thin-film overcoat protective and/or passivation layer of B, or B₄C, or BN, over the rare earth metal nitrides (“REN”), which like the rare earth metals, are unstable and reactive in air as they undergo rapid oxidation. The rare-earth nitrides are important because they show great promise in applications ranging from spintronics, to infrared (“IR”) detectors, and even as contacts to III-V compounds.

For REN, BN might be the favored thin-film boron protective overcoat. Ostensibly, BN has the potential advantage of being able to form a strong bonded transition layer to the REN material by forming interstitial bonds to both the B and N atoms of the BN layer. As a protective coating, BN is extremely hard and chemically stable, even at high temperatures. As an insulator, a thin-film BN protective overcoat/passivation layer could be very thin (e.g., less than 0.01 μm).

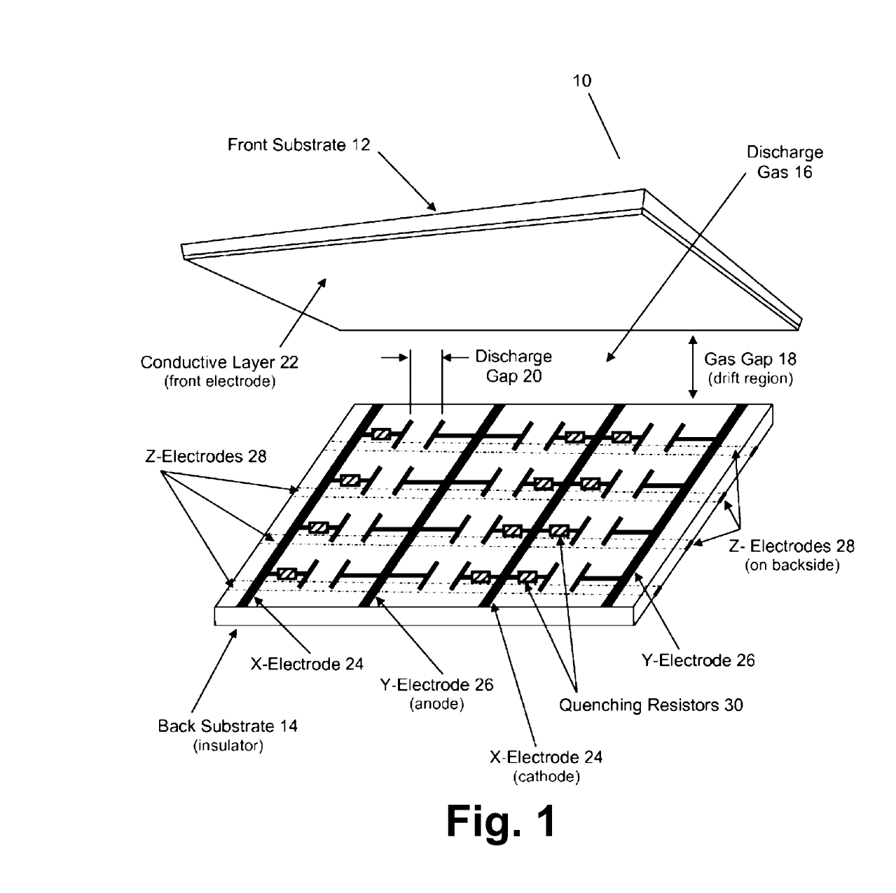

FIG. 1 is a perspective view of a surface-discharge plasma panel sensor (“PPS”) 10 with a parallel/rectilinear surface-discharge electrode pattern incorporating individual cell quenching resistors and a pattern of electrodes that can incorporate the thin-film overcoat layers in accordance with one embodiment. PPS 10 includes a first (front) substrate 12 and a second (back) substrate 14, separated by a gas filled gap 18. Sensor 10 includes X-surface discharge electrodes (cathodes) 24 and Y-surface discharge electrodes (anodes) 26. Detector 10 further includes Z electrodes 28 on the backside of the back substrate 14, quenching resistors 30, and a front conductive layer 22.

PPS 10 is based on surface-discharge, 4-electrode configuration in which the front conductive layer 22 can serve as a front electrode or drift electrode which can also be a thin metal coating. In another embodiment, the front conductive layer can also be a conversion layer or thin sheet such as gadolinium (Gd) foil that can capture a neutral ionizing particle such as a thermal neutron and then emit a fast conversion electron (e.g., 72 keV) into the discharge gas 16. For many applications the PPS front conductive layer 22 can be combined with the front substrate 12 by making the front substrate a metal plate or metal foil. For detector 10, the gas gap is also known as the “drift region” for the discharge gas that fills the region between the front substrate 12 and the back substrate 14.

PPS 10 in one embodiment is a highly integrated array with roughly 10 to 10⁶ micro-detection cells per cm², each of which can act as an independent, position-sensitive, radiation sensor. PPS embodiments, in general, efficiently collect free-electrons and ions created in a gas by the passage of an ionizing particle and then, via the drift field, “channel” the electrons and ions into the higher field region where an avalanche develops leading to breakdown.

A PPS in accordance with one embodiment uses a discharge gas that fills the discharge-gap which defines an orthogonal ion-pair creation drift region of the PPS pixel array 10 of FIG. 1. The electrode configuration of the discharge pixel is defined by a local electrode arrangement forming a capacitive discharge gap coupled to an embedded resistor in the high voltage feed lines. The resistance reduces the electric field during discharge and terminates the pulse.

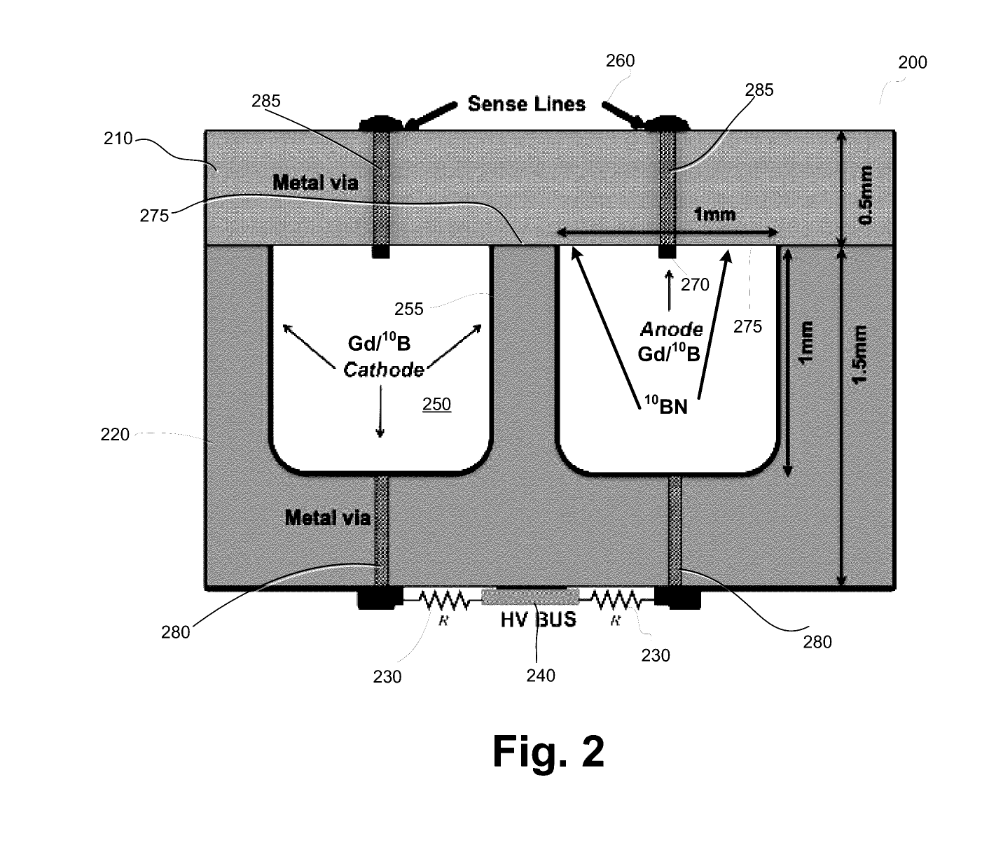

FIG. 2 is a cross-sectional view of microcavity-PPS neutron detector 200 showing two adjacent microcavity pixels in accordance with one embodiment. Embodiments of detector 200 differ in one respect from prior art detectors due to the addition of the thin-film overcoat protective layer. In FIG. 2, chains of successive, isolated cavities, with quench resistors 230 bridging a high voltage (“HV”) bus 240 to a cathode 255, through a conductive via plug 280, establish independent readout sites along the HV bus coordinate (e.g., the X-line) on a rear substrate 220. Parallel chains of sense lines 260 that connect to anodes 270 through a conductive via plug 285 provide an orthogonal coordinate (Y-line) readout on a front substrate 210.

In FIG. 2, surface mount resistors 230 bridge each pixel cathode 255 to HV bus 240. Cover or top/front substrate 210, and microcavity structured back or rear substrate 220 can be fabricated by a variety of PDP thick film manufacturing techniques or laser or mechanically machined from an ultra-low outgas alumina or engineering glass-ceramic material. In other embodiments, the isolation resistors 230 can be implemented with thick-film printed resistors instead of discrete surface mounted resistors. In another embodiment the conductive (metal) via plug 280 on the rear substrate 220 is replaced with a thick-film printed resistive via plug that serves as the quench resistor thereby eliminating the need for the discrete resistor 230. Cavity cathode 255 walls are coated with the disclosed Gd/¹⁰B thin-film coating. A top cover plate 210 is coated on the inside surface 275, facing the cavity discharge gas 250, with a thin-film of ¹⁰BN with the thin-film anode 270 being Gd/¹⁰B.

In considering a suitable protective surface treatment overcoat for the application of Gd as a thin-film conversion layer for Gd-based neutron detectors, such as for front conductive layer 22 of FIG. 1, or the cathode conductive layer 255 of FIG. 2, the overcoat material in addition to being very thin, should preferably also be of low density and low atomic number to minimize back scattering or absorption of the emitted, low-energy Gd conversion electrons. In one embodiment of a microcavity plasma panel sensor based neutron detector, such as sensor 200 of FIG. 2, the thin overcoat layer 255 of FIG. 2 is identified as being ¹⁰B and also functions as the external surface of the device Gd cathode and is directly exposed to bombardment from highly energetic ions created in the high field strength plasma discharge.

In one embodiment, the overcoat material has a low sputtering yield with respect to ion bombardment. Three electrically-conductive elements can be used in one embodiment to provide this feature: Be, B and C, as well as the compound B₄C. Although Be has the lowest density, it has a somewhat higher sputtering yield than either B or C, but more importantly it is toxic and thus requires special handling and so is more difficult to work with. Carbon in the form of either graphite or poly-diamond films is physically acceptable, but diamond, which is the more stable form of carbon, in addition to having a significantly higher density than B, is also orders-of-magnitude less conductive than B which could prove problematic and such films are more difficult to fabricate. Graphite is a good conductor, but is also difficult to fabricate as a film in its pure form without also getting some amount of amorphous carbon which is not stable with respect to physical migration in a plasma discharge environment.

Carbon as graphene can be used if it could be fabricated thick enough and uniformly over the Gd coated “vertical” cathode side walls 255 of a microcavity-PPS based neutron detector of FIG. 2. Thin-films of both graphene and boron can also act as gas barriers for ultra-thin foils and films used for a wide variety of applications, from keeping foodstuffs fresh to hermetically sealing sensor windows and emissive displays such as OLEDs against gas permeation and plugging pinhole “leaks”.

With regard to carbon, there are two known carbides of Gd—GdC₂ and Gd₂C₃. An interstitial Gd—C bonding layer (i.e., interface layer) between either graphite or graphene to Gd is used to provide adhesion in one embodiment. The carbon in B₄C also provides some adhesive benefit in bonding B₄C to Gd. However, the boron atoms themselves are more likely than the carbon atoms in B₄C to form a strong interstitial Gd bond (i.e., Gd—B) as the rare earth borides are well known commercially including their use as cathodes for various applications.

More specifically, all of the rare earth elements form “stable” hexaborides, so by choosing boron in one embodiment a highly adherent hexaboride (GdB₆) interface layer forms that bonds the boron to the gadolinium. Alternatively, a lower polyboride composition adhesion/interface layer is formed, such as the tetraboride (GdB₄) or diboride (GdB₂). In either embodiment, both ¹⁰B and/or ¹⁰B₄C have strong adhesion to Gd via interstitial atoms of boron forming strong covalent Gd—B bonds between the adjacent Gd and B layers.

In this regard GdB₆ is much more stable than Gd metal, as evidenced by the melting point of GdB₆ being 2510° C. versus that of Gd being 1313° C. Further, GdB₆ is stable in moist air, while Gd disintegrates via oxidation as previously discussed. Therefore, in one embodiment, boron is chosen over carbon, with ¹⁰B chosen over ¹⁰B₄C, and a layer of pure ¹⁰B will bond more strongly to Gd than would ¹⁰B₄C. Finally a ¹⁰B thin-film coating is easier to fabricate by electron beam (E-beam) deposition than ¹⁰B₄C.

To demonstrate the viability of embodiments of the invention for application with Gd based neutron detectors, in one embodiment for gaseous micropattern type detectors a thin-film of Gd with a ¹⁰B overcoat was successfully patterned by E-beam deposition (i.e., the ¹⁰B and Gd were deposited within the cavity walls) on several standard microcavity-PPS glass-ceramic (i.e., Macor®) substrates that had been previously pattern coated with thin-film Pt using a Cr adhesion layer. An adhesion layer of ˜0.1 μm of Cr was used for the Gd/¹⁰B deposition. The resulting Cr/Gd/¹⁰B thin-film deposition run on the Pt coated microcavity substrates also included both alumina-ceramic and glass substrate witness slides that were coated at the same time, and which were subsequently used for the test/analysis results summarized below.

Unlike the microcavity glass-ceramic substrates which had been previously coated with Cr/Pt, the ceramic and glass witness slides had no previous metallization and so the Cr adhesion layer was coated directly on the “bare” witness slide substrates. Measurement of the deposited thin-film on the ceramic witness slide by scanning electron microscope (“SEM”) determined that the Gd layer thickness was ˜2.8 μm, with the ¹⁰B overcoat layer thickness ˜0.9 μm. The microcavity substrate size was 56 mm×56 mm and 1.5 mm thick, with each cavity having rectangular dimensions of 1.0 mm×2.0 mm, and being 1.0 mm deep, as shown in FIG. 2.

The initial coating quality observations were made two days after the deposition and reconfirmed more than a year later with the witness slides left open to the ambient atmosphere. Observations indicated that the Cr/Gd/¹⁰B thin-film coating stuck very well to the ceramic substrates and only came off in a few areas on the glass substrates. The patterned areas on the glass substrate held very well. The deposited film on both types of substrates did not show any sign of degradation in the open atmosphere. After several more days of sitting in the open environment, no flaking or degradation of the film could be discerned, and in trying to scrape the coating with a gloved finger, nothing came off. Even after 10 months from the Cr/Gd/¹⁰B deposition, during which the ceramic witness slide had been left in an open Petri dish, continuously exposed to the ambient air/humidity atmosphere, absolutely no flaking or degradation of the thin-film Cr/Gd/¹⁰B coating was observed.

The film has also been observed under a microscope, and rubbed, and lightly adhesion tested using Scotch® tape, and still no flaking or degradation had been observed. However, under a more aggressive Scotch® tape adhesion pull test (i.e. using Scotch® Magic™ Tape No. 810) the entire Cr/Gd/¹⁰B coating did pull off cleanly from some sections of the ceramic witness slide, leaving the substrate “bare” in these sections after 10 months. This adhesion failure to the ceramic substrate could be viewed positively in that it demonstrated that the ¹⁰B to Gd adhesion is, and has remained, very strong, since the tape only made contact with the ¹⁰B top surface layer, and the ¹⁰B pulled with it both the Gd and Cr coatings underneath. Thus not only was the ¹⁰B to Gd adhesion very strong, but also the Gd to Cr adhesion. However the Cr to ceramic substrate adhesion has obviously deteriorated with time and exposure to the ambient atmosphere. It is noted that the cleaning procedure for the glass and ceramic substrates prior to the thin-film deposition was quite minimal and a more aggressive substrate surface cleaning process prior to deposition would help.

The neutron detection efficiency of the Gd/¹⁰B coated microcavity-PPS neutron detector with its Gd/¹⁰B coating over the microcavity cathode walls shown in FIG. 2 can be improved by depositing a thin-film of ¹⁰BN across the inside surface 275 of the top/cover substrate 210 of FIG. 2, prior to fabrication of the small anode electrode 270 centered over the microcavity opening. The efficiency can be further enhanced by employing Gd/¹⁰B for anode 270 located on top of the ¹⁰BN surface layer 275 of FIG. 2. In one embodiment, the ¹⁰BN coating is less than 5 μm thick, and may be on the order of 2 to 3 μm.

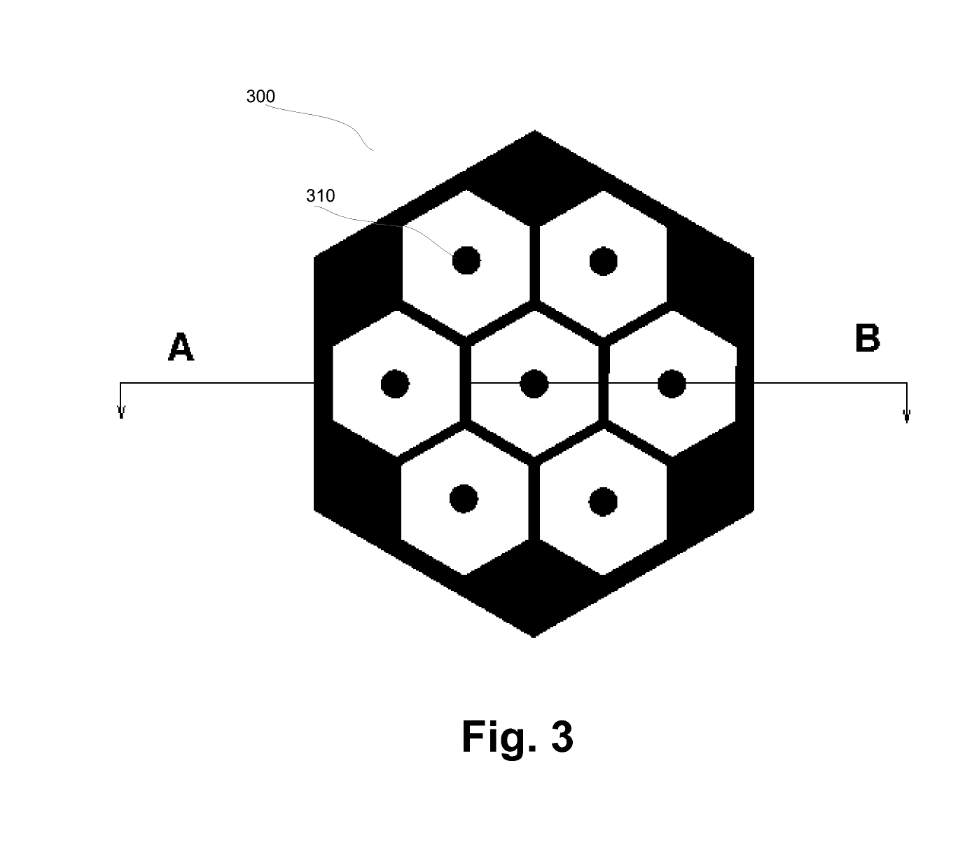

Further, in one embodiment, to maximize the geometric fill-factor for maximum efficiency, the wall thickness between adjacent cavities needs to be minimized. FIG. 3 is a top view of a honeycomb structure 300 with each cavity being hexagon shaped with a staggered row arrangement in accordance with one embodiment. FIG. 3 illustrates part of a three (3) row staggered hexagon cavity configuration and the wall between adjacent cavities. The black circular disk in the center of each hexagon cavity (e.g., disk 310) represents the anode located on the top cover plate substrate (i.e., anode 270 of FIG. 2). In other embodiments, the cavities could be any other shape, including square, rectangular, circular, etc., and these other geometries can also be arranged in a staggered row or column configuration.

In experimental results for one embodiment, the resistivity of the ¹⁰B coating after 10 months of ambient atmosphere exposure was evaluated using pointed probes placed from ˜0.1 to 1 cm apart, and yielded values ranging from hundreds of kΩ to ˜1 MΩ. However, when the probes were pressed down very hard, thereby penetrating the ¹⁰B surface layer to the Gd/Cr base layer beneath, the resistivity dropped by approximately four (4) orders-of-magnitude to less than 50Ω. The pressure required to penetrate the surface layer was considerable, attesting to the hardness of the ˜0.9 μm thin-film ¹⁰B coating. This experiment further demonstrated that although ¹⁰B is a poor conductor, it is not an insulator, and is more than adequate as a cathode if coated as a thin-film over a conductive metal such as Gd, which has ˜80× higher resistivity than Cu. In addition, this experiment revealed a new application for boron coatings in that a thin-film coating of B and/or B₄C, and possibly other non-metals and semiconductors such as nitrides, oxides, silicon, etc., on an insulator or semiconductor substrate surface such as silicon, glass, ceramic, or polymer, can be used for high-resistivity thin-film vertical or conventionally oriented high-resistivity thin-film planar resistors. In the case of B, it was thus demonstrated that ˜1 μm of B will result in a physically stable resistive layer with very high resistivity compared to conventional resistor materials such as nichrome.

Embodiments can be used with thin-film coatings of B and B₄C over other types of Gd or Gd₂O₃ based neutron detectors, including other types of Gd coated gas detectors such as gas electron multipliers (“GEM”), Gd coated vacuum detectors such as multichannel plate (“MCP”) detectors, and Gd coated semiconductor detectors.

Embodiments can be used for other additional applications. For example, one potential application is to improve the physical properties of rare earth magnets, which are known to be extremely brittle and vulnerable to corrosion. Such magnets are usually plated or coated to protect them from breaking, chipping, or crumbling into powder. In particular, neodymium (Nd) magnets are generally considered the strongest and most affordable type of rare earth magnet, and are made of either a sintered or bonded ahoy of neodymium-iron-boron (e.g., Nd₂Fe₁₄B), abbreviated as NIB.

Rare earth magnets are used in numerous applications requiring strong, compact permanent magnets, such as electric motors for cordless tools, hard drives, magnetic hold downs, jewelry clasps, etc. They have a number of excellent magnetic properties, but are more vulnerable to oxidation than samarium-cobalt magnets. Corrosion can cause unprotected NIB magnets to spall off a surface layer, or to crumble into a powder. The use of protective surface treatments such as gold, nickel, zinc and tin plating and epoxy resin coating can provide corrosion protection, but even with such coatings these magnets are still brittle and lack mechanical strength. If however the Nd or NIB particles were B, or B₄C, or BN coated, and even better if they were hot-pressed (i.e., sintered) after being B, or B₄C, or BN coated, then the physical deficiencies of these magnets can be significantly alleviated, including their brittleness and loss of strength upon continuous exposure to humid air.

Further, in connection with stability, for the three protective boron based overcoats disclosed above, BN has the highest melting point of 2967° C. and in its cubic form is almost as hard as diamond and is generally considered to be chemically more stable than diamond. In comparison, B₄C has a melting point of 2350° C., and elemental crystalline B has a melting point of 2077° C. Both B₄C and elemental B are very hard, but neither is as hard as BN.

As disclosed, embodiments use boron based thin-film coatings for rare earth metals and rare earth nitrides to enhance their physical and/or chemical stability, and/or the performance or functionality of such devices based on these materials for a number of different applications. Examples of such applications include gadolinium (Gd) based neutron detectors, rare earth based magnets, infrared detectors, and a variety of spintronic devices such as for memory storage, magnetic sensors, and for quantum computing. Further, the coatings in accordance to embodiments can also be used for achieving high resistivity in thin-film based devices including both vertical and planar resistors.

Several embodiments are specifically illustrated and/or described herein. However, it will be appreciated that modifications and variations of the disclosed embodiments are covered by the above teachings and within the purview of the appended claims without departing from the spirit and intended scope of the invention.

What is claimed is:

1. An apparatus comprising:
a first layer comprising a rare earth element; and
a thin-film coating layer deposited on the first layer, the thin-film coating layer comprising boron.

2. The apparatus of claim 1, wherein the thin-film coating layer comprises one of elemental boron (B), boron carbide (B₄C), or boron nitride (BN).

3. The apparatus of claim 2, wherein the rare earth element comprises one of gadolinium (Gd), europium (Eu), lanthanum (La) or neodymium (Nd).

4. The apparatus of claim 3, wherein the rare earth element comprises its oxide form of Gd₂O₃, Eu₂O₃, La₂O₃, or Nd₂O₃.

5. The apparatus of claim 3, wherein the first layer is deposited on a metal, ceramic, glass or polymer substrate.

6. The apparatus of claim 5, comprising the rare earth element Gd or Gd₂O₃ on the first layer, wherein the thin-film coating comprises one of elemental boron (B), boron carbide (B₄C) or boron nitride (BN).

7. The apparatus of claim 6, wherein the boron is present as the boron-10 isotope, comprising a thin-film coating of one of elemental boron (¹⁰B), boron carbide (¹⁰B₄C) or boron nitride (¹⁰BN).

8. The apparatus of claim 7, comprising a second substrate coupled to a first substrate through a gas-discharge media, wherein the second substrate is coated with a plurality of electrodes.

9. The apparatus of claim 8, wherein the first and second substrates and the gas gas-discharge media provide a neutron detector functionality.

10. The apparatus of claim 9, wherein one of the first or second substrates comprises a plurality of anodes, and the other one of the first or second substrates comprises a plurality of cathodes.

11. A method of manufacturing an apparatus comprising:
forming a first layer comprising a rare earth element; and
depositing a thin-film coating layer on the first layer, the thin-film coating layer comprising boron (B), boron carbide (B₄C), or boron nitride (BN).

12. The method of claim 11, wherein the thin-film coating layer comprises one of elemental boron (B), boron carbide (B₄C), or boron nitride (BN).

13. The method of claim 12, wherein the rare earth element comprises one of gadolinium (Gd), europium (Eu), lanthanum (La) or neodymium (Nd).

14. The method of claim 13, wherein the rare earth element comprises its oxide form of Gd₂O₃, Eu₂O₃, La₂O₃, or Nd₂O₃.

15. The method of claim 13, wherein the first layer is deposited on a metal, ceramic, glass or polymer substrate.

16. The method of claim 15, comprising the rare earth element Gd or Gd₂O₃ on the first layer, wherein the thin-film coating comprises one of elemental boron (B), boron carbide (B₄C) or boron nitride (BN).

17. A high-resistivity thin-film resistor comprising:
an insulator or semiconductor substrate surface; and
a high-resistivity thin-film coating of boron (B) or boron carbide (B₄C) on the insulator or semiconductor substrate surface.

18. The apparatus of claim 17, wherein the insulator substrate surface is one of ceramic, glass or polymer.

19. The apparatus of claim 17, wherein the high-resistivity thin-film coating on the insulator or semiconductor substrate surface forms in a vertical resistor configuration.

20. The apparatus of claim 17, wherein the high-resistivity thin-film coating on the insulator or semiconductor substrate surface forms a planar resistor configuration.
